(19) United States
(12) Patent Application Publication
(10) Pub. No.: US 2020/0319383 A1
(43) Pub. Date: Oct. 8, 2020

(54) DISPLAY MODULE OF DISPLAY DEVICE

(71) Applicant: HONG FU TAI PRECISION ELECTRONS (YANTAI) CO., LTD., Yantai (CN)

(72) Inventors: JING WANG, Yantai (CN); JING-XIAO YUAN, Yantai (CN); QING-XIN ZHENG, Yantai (CN); LI-JUN YANG, Yantai (CN); GUO-DONG WU, Yantai (CN)

(21) Appl. No.: 16/418,435

(22) Filed: May 21, 2019

(30) Foreign Application Priority Data
Apr. 2, 2019 (CN) 201910259637.5

(51) Int. Cl. G02B 5/02; H05K 5/00; G02B 27/09; G09G 3/22

(52) U.S. Cl. CPC G02B 5/0205; G09G 3/22; G02B 27/0977; H05K 5/0017

(57) ABSTRACT

A display module includes a backplane, a front frame, a diffusion plate, and a display panel. The display panel is fixedly coupled to the front frame. The backplane includes a base plate and a side plate. The side plate is fixedly coupled to the base plate. The base plate is spaced apart from and opposite to the display panel. At least one backlight is disposed on a side of the base plate facing the display panel. The side plate extends from an end of the base plate to the front frame and cooperatively defines a receiving space with the front frame. The diffusion plate is disposed between the backplane and the display panel and is fixedly mounted within the receiving space.

### FIELD

The subject matter herein generally relates to display devices, and more particularly to a display module of a display device.

### BACKGROUND

Generally, a display module includes a front frame, a backplane, a display panel, a diffusion plate, an optical film set, and a middle frame. The front frame and the backplane cooperatively define a receiving space, and the display panel, the optical film set, the diffusion plate, and the middle frame are received within the receiving space. However, the middle frame occupies much of the receiving space.

### BRIEF DESCRIPTION OF THE DRAWINGS

Implementations of the present disclosure will now be described, by way of embodiments, with reference to the attached figures.

FIG. 1 is an isometric view of an embodiment of a display device.

FIG. 2 is a schematic structural diagram of a first embodiment of a display module.

FIG. 3 is a schematic structural diagram of a second embodiment of a display module.

FIG. 4 is a schematic structural diagram of a third embodiment of a display module.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections.

The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder.

The term “comprising” means “including, but not necessarily limited to”; it specifically indicates open-ended inclusion or membership in a so-described combination, group, series and the like.

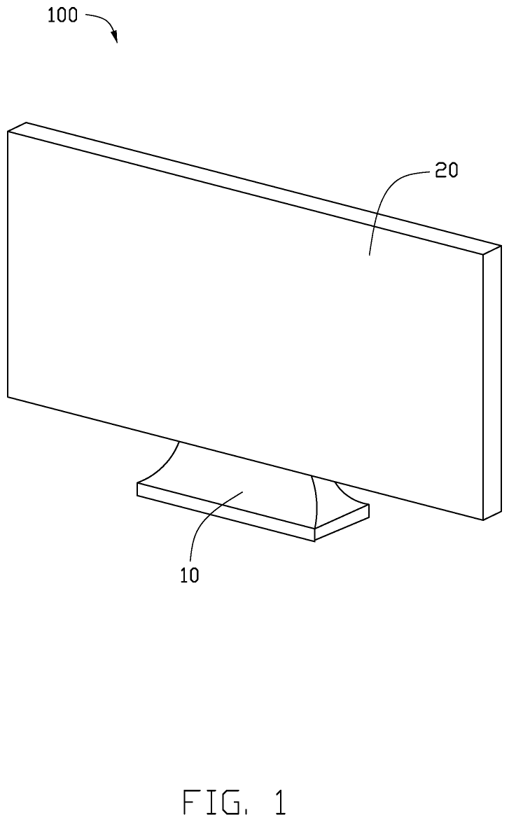

FIG. 1 shows an embodiment of a display device 100 including a support stand 10 and a display module 20. The display module 20 is mounted on the support stand 10. The display device 100 may be, but is not limited to, a television, a display monitor, a billboard, or the like.

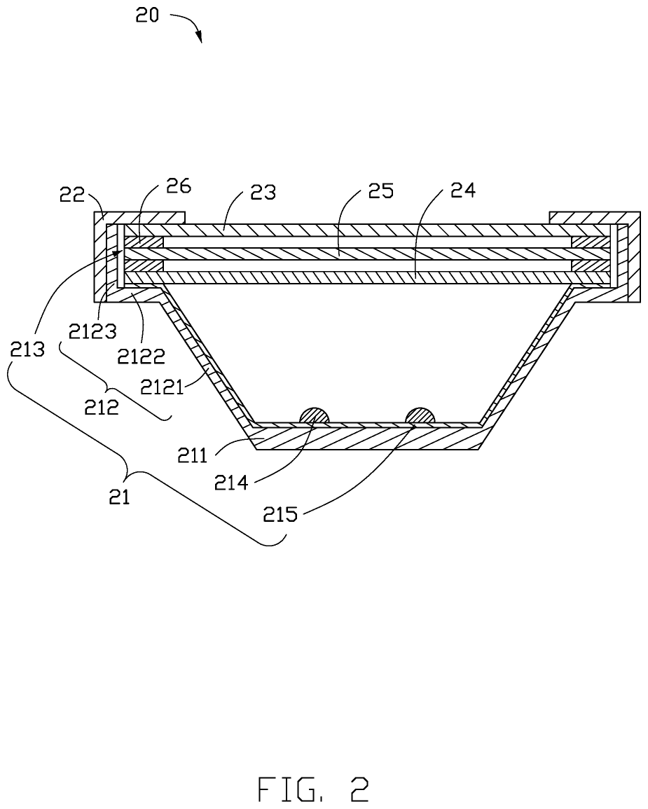

FIG. 2 shows a schematic structural diagram of a first embodiment of the display module 20. The display module 20 includes a backplane 21, a front frame 22, a display panel 23, a diffusion plate 24, an optical film set 25, and a colloid 26.

The backplane 21 includes a base plate 211 and a side plate 212. The side plate 212 is fixedly coupled to the front frame 22. The side plate 212 extends from an end of the base plate 211 to the front frame 22 and cooperatively defines a receiving space 213 with the front frame 22. The base plate 211 is spaced apart from and opposite to the display panel 23, and at least one backlight 214 is disposed on a side of the base plate 211 facing the display panel 23. The display panel 23, the optical film set 25, and the diffusion plate 24 are sequentially stacked and are fixedly mounted within the receiving space 213. A colloid 26 is disposed between the display panel 23 and the optical film set 25 and between the optical film set 25 and the diffusion plate 24 to bond the display panel 23, the optical film set 25, and the diffusion plate 24.

The backplane 21 is substantially U-shaped. The side plate 212 includes an inclined portion 2121, a support portion 2122, and a bent portion 2123. The inclined portion 2121 is inclined relative to the base plate 211 and the support portion 2122. One end of the inclined portion 2121 is fixedly coupled to the base plate 211, and another end of the inclined portion 2121 is fixedly coupled to the support portion 2122. The support portion 2122 is substantially parallel to the base plate 211 for supporting the display panel 23, the diffusion plate 24, and the optical film set 25. The bent portion 2123 extends from an end of the support portion 2122 away from the inclined portion 2121 and extends toward the front frame 22. The bent portion 2123 is substantially perpendicular to the support portion 2122 and is fixedly coupled to the front frame 22. The receiving space 213 is cooperatively defined by the support portion 2122, the bent portion 2123, and the front frame 22.

A reflective film 215 is disposed on a side of the backplane 21 facing the display panel 23, and the backlight 214 is disposed on the reflective film 215. Specifically, the reflective film 215 is disposed on the base plate 211, the inclined portion 2121, and partially on the support portion 2122 for reflecting light emitted by the backlight 214 to the diffusion plate 24.

The front frame 22 is substantially L-shaped. One side of the front frame 22 is fixedly coupled to the bent portion 2123, and another side of the front frame 22 cooperatively defines the receiving space 213 with the support portion 2122 and the bent portion 2123.

The display panel 23 may be a thin film transistor-liquid crystal display (TFT-LCD), which may include, disposed in order from top to bottom, an upper polarizer, a color film substrate (also referred to as a counter electrode substrate), a liquid crystal layer, an array substrate, and a lower polarizer. In other embodiments, the display panel 23 can adopt other forms or structures.

The diffusion plate 24 is a diffusion film having a haze of 90% to 99% and a transmittance of 40% to 60%, and a thickness of the diffusion plate 24 is about 0.1 to about 0.5 mm. In other embodiments, the thickness of the diffusion plate 24 can be adjusted according to actual conditions, and the haze and transmittance thereof are not limited to the range selected in the embodiment.

The optical film set 25 includes at least one of a prism film, a diffusion film, a micro prism film, a brightness enhancement film, a composite film, and a reflective film. The colloid 26 includes at least one of a pressure sensitive adhesive, a water gel, and an ultraviolet (UV) glue.

The side panel 212 extends from the ends of the base plate 211 toward the front frame 22 and defines the receiving space 213 with the front frame 22. The diffusion plate 24 is located between the backplane 21 and the display panel 23 and is fixedly mounted within the receiving space 213, which not only overcomes the RA problem in the related art of a multilayer composite film sticking to the display panel, but also omits a middle frame to reduce a volume and a weight of the display module 20, thereby saving manufacturing costs.

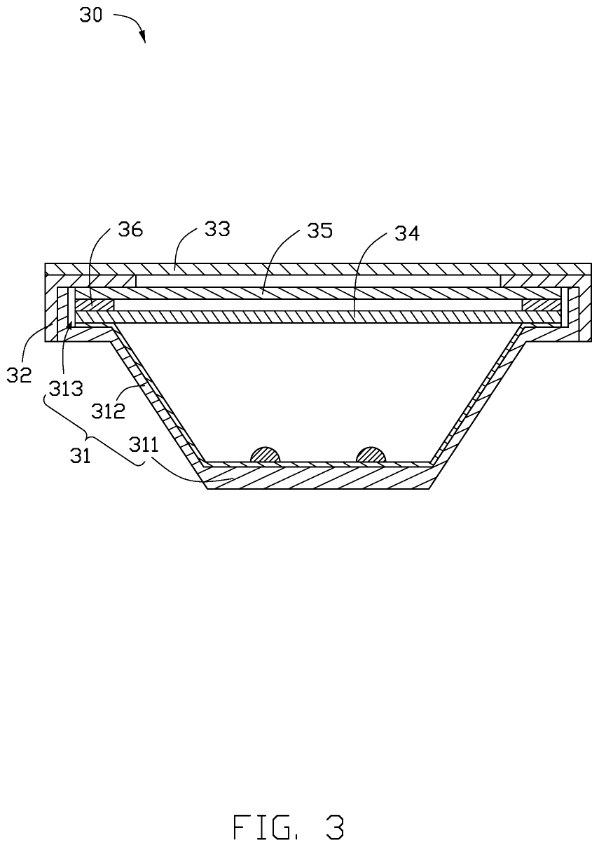

FIG. 3 shows a schematic structural diagram of a second embodiment of a display module 30. The display module 30 includes a backplane 31, a front frame 32, a display panel 33, a diffusion plate 34, an optical film set 35, and a colloid 36. The backplane 31 includes a base plate 311 and at least one side plate 312 fixedly coupled to the front frame 32. The side plate 312 extends from an end of the base plate 311 toward the front frame 32 and cooperatively defines a receiving space 313 with the front frame 32. A difference between the display module 30 and the display module 20 is that the display panel 33 is fixedly coupled to a side of the front frame 32 facing away from the base plate 311, and the optical film set 35 and the diffusion plate 34 are fixedly mounted within the receiving space 313. A colloid 36 is disposed between the optical film set 35 and the diffusion plate 34 to bond the optical film set 35 and the diffusion plate 34.

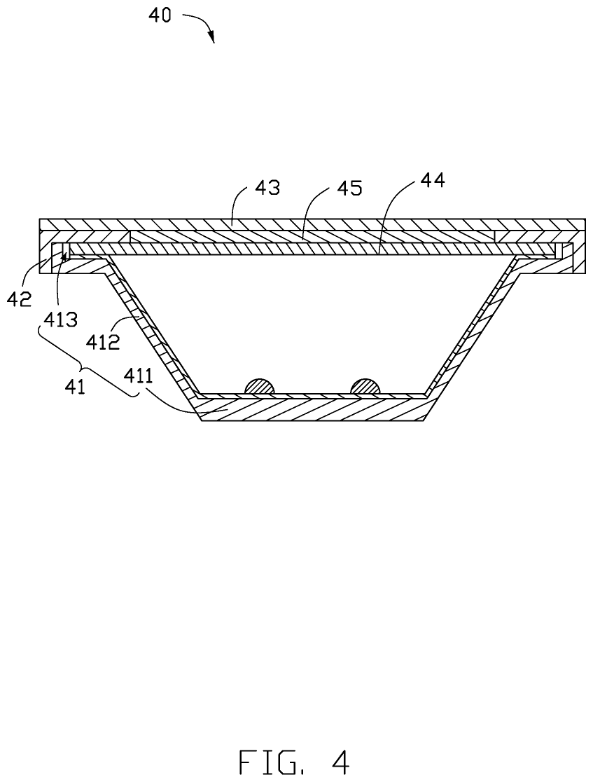

FIG. 4 shows a schematic structural diagram of a third embodiment of a display module 40. The display module 40 includes a backplane 41, a front frame 42, a display panel 43, a diffusion plate 44, and an optical film set 45. The backplane 41 includes a base plate 411 and at least one side plate 412 fixedly coupled to the front frame 42. The side plate 412 extends from an end of the base plate 411 toward the front frame 42 and cooperatively defines a receiving space 414 with the front frame 42. The display panel 43 is fixedly coupled to a side of the front frame 42 facing away from the base plate 411. A difference between the display module 40 and the display module 30 is that only the diffusion plate 44 is fixedly mounted within the receiving space 414. The optical film set 45 is located between the display panel 43 and the diffuser 44. The optical film set 45 has a same thickness as the front frame 42 and abuts against an inner edge of the front frame 22 and is surrounded by the front frame 22. Another difference between the display module 40 and the display module 30 is that there is no colloid between the optical film set 45 and the diffusion plate 44.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A display module comprising:
a backplane;
a front frame;
a diffusion plate; and
a display panel fixedly coupled to the front frame; wherein:
the backplane comprises a base plate and a side plate;
the side plate is fixedly coupled to the base plate;
the base plate is spaced apart from and opposite to the display panel;
at least one backlight is disposed on a side of the base plate facing the display panel;
the side plate extends from an end of the base plate to the front frame and cooperatively defines a receiving space with the front frame;
the diffusion plate is disposed between the backplane and the display panel and is fixedly mounted within the receiving space.

2. The display module of claim 1, wherein:
the side plate comprises an inclined portion and a support portion;
the inclined portion is inclined relative to the side plate and the support portion;
one end of the inclined portion is fixedly coupled to the base plate, and another end of the inclined portion is fixedly coupled to the support portion;
the receiving space is defined by the support portion and the front frame.

3. The display module of claim 1 further comprising a reflective film, wherein:
the reflective film is disposed on a side of the backplane facing the display panel;
the at least one backlight is disposed on the reflective film;
the reflective film is configured to reflect light emitted from the at least one backlight to the diffusion plate.

4. The display module of claim 1 further comprising an optical film set disposed between the display panel and the diffusion plate.

5. The display module of claim 4, wherein:
the optical film set comprises at least one of a prism film, a diffusion film, a micro prism film, a brightness enhancement film, a composite film, and a reflective film.

6. The display module of claim 4, wherein:
the colloid comprises at least one of a pressure sensitive adhesive, a water gel, and an ultraviolet glue.

7. The display module of claim 4, wherein:
the display panel, the optical film set, and the diffusion plate are arranged in sequence within the receiving space;
a colloid is disposed between the display panel and the optical film set and between the optical film set and the diffusion plate to bond the display panel, the optical film set, and the diffusion plate.

8. The display module of claim 4, wherein:
the display panel, the optical film set, and the diffusion plate are arranged in sequence;
the display panel is fixedly coupled to a side of the front frame facing away from the base plate;
the optical film set and the diffusion plate are arranged within the receiving space;
a colloid is disposed between the optical film set and the diffusion plate to bond the optical film set and the diffusion plate.

9. The display module of claim 4, wherein:
the display panel, the optical film set, and the diffusion plate are arranged in sequence;
the display panel is fixedly coupled to a side of the front frame facing away from the base plate;
the optical film set abuts against an inner edge of the front frame and is surrounded by the front frame;
the diffusion plate is arranged within the receiving space.

10. A display device comprising:
a support stand; and
a display module mounted on the support stand, the display module comprising:
a backplane;
a front frame;
a diffusion plate; and
a display panel fixedly coupled to the front frame; wherein:
the backplane comprises a base plate and a side plate;
the side plate is fixedly coupled to the base plate;
the base plate is spaced apart from and opposite to the display panel;
at least one backlight is disposed on a side of the base plate facing the display panel;
the side plate extends from an end of the base plate to the front frame and cooperatively defines a receiving space with the front frame;
the diffusion plate is disposed between the backplane and the display panel and is fixedly mounted within the receiving space.

11. The display device of claim 10, wherein:
the side plate comprises an inclined portion and a support portion;
the inclined portion is inclined relative to the side plate and the support portion;
one end of the inclined portion is fixedly coupled to the base plate, and another end of the inclined portion is fixedly coupled to the support portion;
the receiving space is defined by the support portion and the front frame.

12. The display module of claim 10 further comprising a reflective film, wherein:
the reflective film is disposed on a side of the backplane facing the display panel;
the at least one backlight is disposed on the reflective film;
the reflective film is configured to reflect light emitted from the at least one backlight to the diffusion plate.

13. The display module of claim 10 further comprising an optical film set disposed between the display panel and the diffusion plate.

14. The display module of claim 13, wherein:
the optical film set comprises at least one of a prism film, a diffusion film, a micro prism film, a brightness enhancement film, a composite film, and a reflective film.

15. The display module of claim 13, wherein:
the colloid comprises at least one of a pressure sensitive adhesive, a water gel, and an ultraviolet glue.

16. The display module of claim 13, wherein:
the display panel, the optical film set, and the diffusion plate are arranged in sequence within the receiving space;
a colloid is disposed between the display panel and the optical film set and between the optical film set and the diffusion plate to bond the display panel, the optical film set, and the diffusion plate.

17. The display module of claim 13, wherein:
the display panel, the optical film set, and the diffusion plate are arranged in sequence;
the display panel is fixedly coupled to a side of the front frame facing away from the base plate;
the optical film set and the diffusion plate are arranged within the receiving space;
a colloid is disposed between the optical film set and the diffusion plate to bond the optical film set and the diffusion plate.

18. The display module of claim 13, wherein:
the display panel, the optical film set, and the diffusion plate are arranged in sequence;
the display panel is fixedly coupled to a side of the front frame facing away from the base plate;
the optical film set abuts against an inner edge of the front frame and is surrounded by the front frame;
the diffusion plate is arranged within the receiving space.
